(19) United States
(12) Patent Application Publication
(10) Pub. No.: US 2021/0117594 A1
(43) Pub. Date: Apr. 22, 2021

(54) METHOD FOR CREATING A DIGITAL TWIN

(71) Applicant: Siemens Aktiengesellschaft, 80333 München (DE)

(72) Inventor: JOHANNES LEHNER, Fürth (DE)

(73) Assignee: Siemens Aktiengesellschaft, 80333 München (DE)

(21) Appl. No.: 17/252,993

(22) PCT Filed: May 17, 2019
(86) PCT No.: PCT/EP2019/062777

§ 371 Date: Dec. 16, 2020

(30) Foreign Application Priority Data
Jun. 20, 2018 (EP) 18178790.4

(51) Int. Cl. G06F 30/20; G06F 30/12; G06K 9/62

(52) U.S. Cl. CPC G06F 30/20; G06K 9/6267; G06F 30/12

(57) ABSTRACT

On the basis of provided product knowledge, a software object which functions as a digital twin of a technical product is created. The product knowledge is available in an automatically processable form and comprises, as object variants, data records having data for different variants of at least one component of the technical product. The object variants are each assigned an object variant classification, which functions as a unique identifier, as well as geometric data and positional data. Each object variant, the object variant classification of which matches a predetermined or predeterminable article code, is processed as belonging to the digital twin. For each object variant belonging to the digital twin, the, or each, geometric object described by the geometric data of the object variant is positioned corresponding to the positional data of the object variant.

The invention relates to a method for creating a digital twin of a technical product. A digital twin is a software object, which represents the respective technical product.

During the age of industry 4.0, ever increasing requirements are developing on the direct and indirect outputs of a technical product. Aside from the direct technical features of a product, for instance installation space or output, increased attention must also be paid to the indirect features. In the industrial environment this includes a customer, when purchasing a technical product, nowadays expecting also to obtain its digital twin, in addition to the data relating to its weight, center of gravity and dimension drawing, which digital twin can be used for installation planning, for instance.

An object of the invention consists in specifying a particularly simple method for creating a digital twin.

This object is achieved according to the invention by means of a method having the features of claim 1. The following is provided here to create a software object which functions as a digital twin of a technical product:

The creation of the digital twin is carried out on the basis of the available product knowledge. This is available in an automatically processable form. The product knowledge comprises data records with data for different variants of at least one component of the respective technical product or data records with data for different variants of different components of different technical products. Such data records are referred to below as object variants.

An object variant classification which functions as a unique identifier is assigned to the object variants in each case. Furthermore, at least geometric data and positional data are assigned to the object variants in each case.

In order to create the digital twin of a technical product, an article code of the respective technical product is entered or selected, for instance. An automatic selection of individual object variants is carried out on the basis of the article code. For all object variants included in the product knowledge, this selection comprises the check to determine whether their object variant classification and the respective article code match one another. Whenever this is the case, the respective object variant is processed as belonging to the digital twin or included in the digital twin, for instance by the data of the respective object variant or essential data of the object variant being added, directly or indirectly, to the software object under development, the digital twin. During an evaluation of the data of the generated digital twin, for each object variant which belongs to the digital twin, the or each geometric object described by means of the geometric data of the respective object variant is positioned according to the positional data of the respective object variant.

The advantage of the invention consists in the digital twin being developed on the basis of the product knowledge and in this way already available data being reused.

The invention is thus an automatic extraction of the data required to create a digital twin of a specific technical product from a database with product knowledge. The database comprises the product knowledge in the form of a complete description of the respective technical product, for instance in the form of CAD data. This complete description also comprises the afore-cited object variants, in other words, for instance, a description of different components or those which vary in respect of their design and/or position, in particular in the form of CAD data. To ensure that such object variants can be used within the scope of the approach proposed here and can be located automatically, it is only necessary to identify the respective data with a unique object variant classification.

As a result of the method, a weight value and/or center of gravity is determined by taking all object variant data belonging to the digital twin into account. The determined weight value or center of gravity corresponds to the weight value or center of gravity of the technical product represented by means of the digital twin.

Advantageous embodiments of the invention form the subject matter of the subclaims. References used here within the claims point to the further embodiment of the object of the referenced claim by the features of the respective dependent claim. They are not to be understood as an abdication of achieving an independent objective protection for the features or combinations of features of a dependent claim. Furthermore, with respect to an interpretation of the claims and the description with a closer specification of a feature in a dependent claim, it should be assumed that a restriction of this type in the respective preceding claims and a more general embodiment of the present method is not present. Each reference in the description to aspects of dependent claims is accordingly to be read expressly as a description of optional features even without any special reference.

In a further embodiment of the method, the object variant data is stored in the resulting software object, the digital twin. The digital twin has become independent of the product knowledge and/or its availability as a result of the takeover of object variant data. The digital twin, in other words the software object, can therefore also be forwarded to a third party, for instance, which has no access to the product knowledge or should have no access of this type.

In another further embodiment of the method, expressions in a formal language, for instance regular expressions, function as an object variant classification. The use of expressions in a formal language, especially the use of regular expressions, allows for the integration of the method proposed here into an advanced data processing, for instance a data processing of a manufacturer of electric motors. The respective technical products, in other words, for instance, electric motors, are in any case regularly referred to within such a data processing in machine-readable form, in particular by means of an article code in the form of a machine-readable product designation (MLFB). This data, which results for instance on account of construction data, for instance CAD data, can be used as product knowledge. This ensures that the digital twin in particular with respect to its geometry and with respect to its measurements matches exactly with the respectively represented technical product.

The method described below is preferably realized in the form of a computer program for automatic execution. The invention is therefore on the one hand also a computer program with program code instructions which can be executed by a computer and on the other hand a storage medium with a computer program of this type, in other words a computer program product with program code means, as well as finally also a computer known essentially per se or a computer system known essentially per se, in the memory of which such a computer program is or can be loaded as means for carrying out the method and its embodiments.

An exemplary embodiment of the invention is explained in more detail below on the basis of the drawing. Objects or elements which correspond to one another are provided with the same reference characters in all the figures, in which

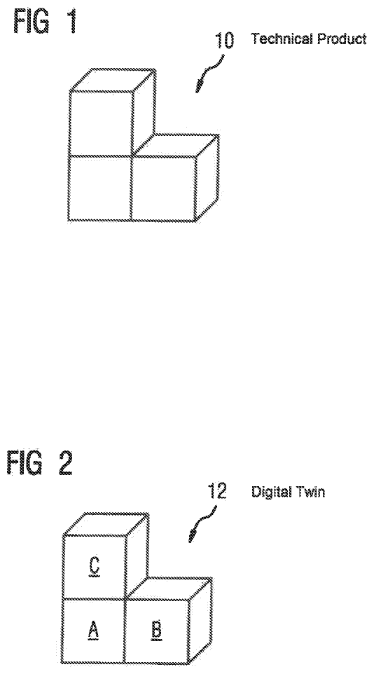

FIG. 1 shows a technical product,

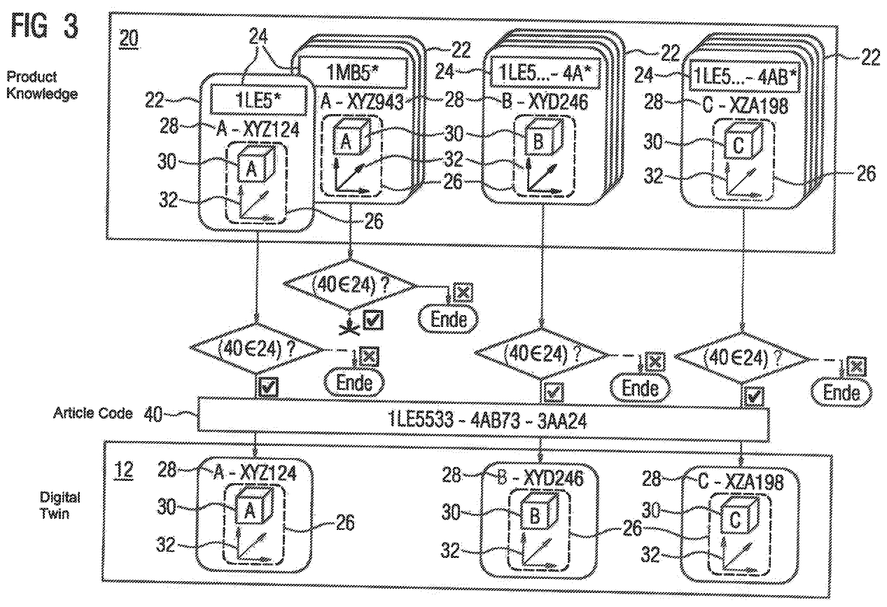

FIG. 2 shows a digital twin representing the technical product in FIG. 1,

FIG. 3 shows a schematically simplified illustration of a generation of a digital twin, and

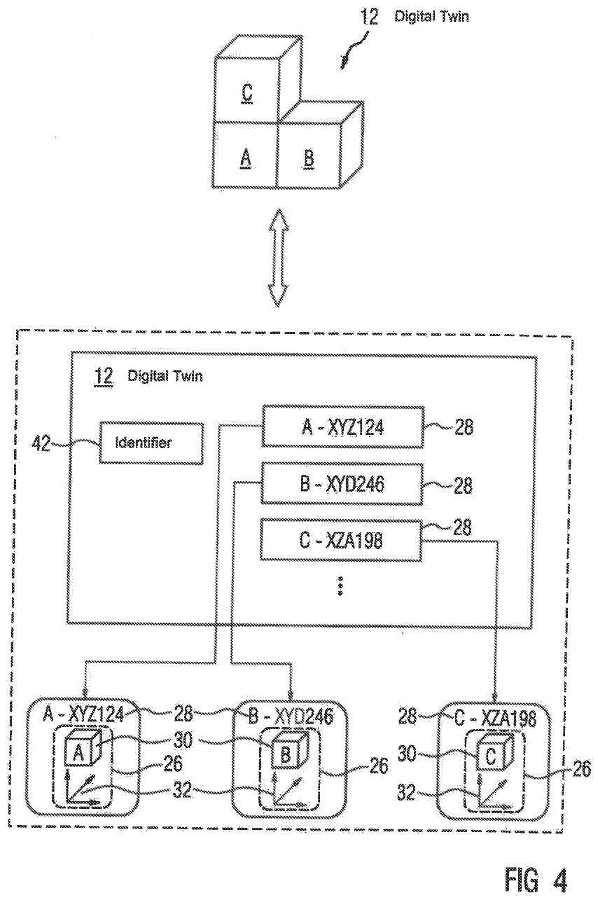

FIG. 4 shows a digital twin resulting on account of a generation according to FIG. 3.

In the interests of a linguistically simple further description, the representation in FIG. 1 shows a schematically very simplified real technical product 10. The product 10 is an electric motor, for instance. Similarly, the product 10 can be a chair, for instance. The type of the product 10 is irrelevant.

A so-called digital twin 12, in other words a software object, which describes the essential properties of the respective technical product 10, is to be created for generally any technical product 10. The resulting software object is the digital twin 12 and correspondingly the terms digital twin 12 and software object are used synonymously.

The representation in FIG. 2 shows a digital twin 12 representing the technical product 10 in FIG. 1. The graphical representations on the one hand of the technical product 10 (FIG. 1) and on the other hand of the digital twin 12 (FIG. 2) representing this can naturally barely be differentiated. The representation of the digital twin 12 in FIG. 2 also comprises symbolic identifiers of the objects included in the digital twin 12.

Evidently the technical product 10 according to FIG. 1 in the example shown comprises three individual objects. These are in this case, but only by way of example, cubes. The objects (cubes) are arranged in a specific geometric relation relative to one another: a second cube is located adjacent to a first cube and a third cube is located on the first cube. In the representation of the digital twin 12 in FIG. 2, the three cubes are referred to symbolically with “A” (first cube), “B” (second cube) and “C” (third cube).

The representation in FIG. 2 essentially already shows the result of creating a digital twin 12 for a real technical product 10. The method to automatically obtain such a digital twin 12 is described below.

A digital twin 12, as its name already suggests, is a correspondence, via data technology, of a respective technical product 1 to be shown. Therefore a digital twin 12 is understood in the broadest sense to mean a data record which comprises directly or indirectly all the data which is required to describe the relevant properties of the technical product 10, in particular the geometric properties of the technical product 10 and/or properties connected thereto. These relevant technical properties are for instance the measurements of the technical product 10, a dimension of a cladding contour around the technical product 10, the weight of the technical product 10, a center of gravity of the technical product 10, etc.

To generate correspondences, via data technology, of the physical objects included in the technical product 10 to be represented within the digital twin 12, individual objects can theoretically be applied, for instance drawn individually by means of a CAD program and then summarized to form the digital twin 12. This would indicate a graphical representation of the represented technical product 10 but does not allow properties to be taken into consideration such as the weight or the center of gravity of the technical product 10, for instance. Moreover, a renewed generation of such objects is unnecessarily complicated, since these are typically developed in conjunction with a development and/or manufacture of the respective technical product 10.

The data of such objects, referred to below as “product knowledge” 20 (FIG. 3), is therefore advantageously relied upon for the automatic creation of a digital twin 12.

The representation in FIG. 3 illustrates in a schematically simplified manner the method proposed here for creating a digital twin 12. A digital twin 12 is a data record in the memory of a computer which is developed during the course of the method. For the further description, in the interests of improved legibility, with a use of a term, for instance the term “digital twin” 12, reference is not expressly made to this in each case referring to a data record in the memory of a computer. This is always to be read correspondingly below and also applies to other elements and the data records underlying these in each case.

The approach is based on already existing product knowledge 20 being used. The product knowledge 20 is available in an automatically processible form, namely in the form of a database (the database represents the product knowledge 20 and comprises the product knowledge 20) with object variants 22 (data records), which describe a variant of a component of a specific technical product 10 in each case. With an electric motor as a technical product 10, different terminal boxes are conceivable as variants, for instance, which differ in respect of their geometry and/or in respect of their position relative to a housing (stator housing) of the electric motor. The product knowledge 20 then comprises corresponding object variants 22. With a complex product, such as for instance with an electric motor, essentially all components included here are considered and displayed in the form of object variants 22 (for instance housing with or without cooling fins, housing with different cooling fins motor shafts of different lengths, etc.).

Each object variant 22 (data record) comprises an object variant classification 24. This functions as a unique identifier of the respective object variant 22. Provision is preferably made for an object variant classification 24 to classify an object variant 22 according to basic alphanumeric rules and for it to be geared toward an article code 40 of a technical product 10, for instance.

Each object variant 22 comprises object variant data 26 (data record), in particular object variant data 26 and a unique object variant ID 28. At least geometric data 30 and positional data 32 belong to the object variant data 26. The geometric data 30 (data record) describes at least one geometric object, in other words, for instance, a cube, a cylinder or such like, which belongs to the respective object variant 22. With a complex spatial form of a variant, a plurality of geometric objects belongs to the respective object variant 22 and the geometric data 30 comprises the totality of the geometric objects.

The geometric data 30 relates to a local coordinate system. The positional data 32 describes the position of the totality of the objects described by means of the geometric data 30 relative to a respective technical product 10. The geometric data 30 describes, for instance, at least one geometric object, which represents a terminal box of an electric motor. The positional data 32 describes its position on the electric motor, for instance on the top of the stator housing or to the side of the stator housing.

An article code 40 functions as the basis of the specification of the digital twin 12. Within the scope of the method, the article code 40 specifies the specific technical product 10 for which a digital twin 12 is to be generated. An article code 40 refers in each case to precisely one specific technical product 10 in a specific embodiment, in other words, for instance, an electric motor of a specific power level and with further properties, wherein the fact that the terminal box of the electric motor is attached to the side belongs to the further properties, for instance. Within the scope of the method, the article code 40 is entered or selected from a set of article codes 40, in particular a quantity of generated article codes 40.

Object variants 22, which relate to different terminal boxes and/or terminal boxes at different positions, belong to the product knowledge 20, for instance. Each object variant 22, in which the object variant classification 24 thereof and the article code 40 match one another, is processed as belonging to the digital twin 12, wherein each object can only comprise a valid object variant 22. An object variant classification 24 then matches with an article code 40, for instance, if the object variant classification 24 or a part of the object variant classification 24 is contained in the article code 40. Whether the object variant classification 24 or a part of the object variant classification 24 is contained in the article code 40 is checked for instance by means of string operations essentially known per se.

With an alternative testing method, it is assumed that the object variant classification 24 is present in the form of a regular expression. The object variant classification 24 therefore defines a quantity. For instance, an object variant classification 24 such as “1LE5*” defines, on the basis of the asterisk which functions as a placeholder, an unlimited quantity of strings, in which each string included therein begins with “1LE5”. The continuation of the string following on from “1LE5” is irrelevant. The strings included in the quantity can be any length provided they comprise “1LE5” as first characters and following on from “1LE5” any characters. With this testing method, the object variant classification 24, in other words for instance “1LE5*” and the article code 40, for instance “1LE5533-4AB73-3AA24” match with one another, because the article code 40 is an element of the quantity defined by the object variant classification 24.

In the representation in FIG. 3, the check carried out automatically when the method proposed here is executed to determine whether an object variant classification 24 matches with a respective article code 40 is shown graphically in a schematically simplified manner. The check to determine whether an object variant classification 24 matches the respective article code 40 is expressed in the representation with reference to the reference characters used for the object variant classification 24 and the article code 40 and is written in each case within a flow chart symbol for a branching (differentiation) as “(40ϵ24)?”.

In the situation shown, the article code 40 (“1LE5533-4AB73-3AA24”) belongs to the quantity defined by the object variant classification 24 “1LE5*” in the form of a regular expression. As a result, the object variant 22 with this object variant classification 24 was identified below as belonging to the digital twin 12. On the other hand, the afore-cited article code 40 does not belong to the quantity defined by the object variant classification 24 “1MB5*”. The corresponding object variant 22 is therefore not part of the digital twin 12. For the other object variant classifications 24 shown by way of example in FIG. 3, this applies accordingly.

The product knowledge 20 is searched in order to automatically create a digital twin 12. This means that all object variants 22 which form the product knowledge 20 or a predetermined or predeterminable subset of the object variants 22 forming the product knowledge 20 are checked in the above-described manner. Whenever the result of the check is positive, the object variant 22 (referred to by the object variant classification 24) belonging to the respective object variant classification 24 is processed as belonging to the digital twin 12, wherein each object can only comprise a valid object variant 22. This belonging is shown in the representation in FIG. 3 in the form of a representation of the object variant data 28 and the object variant ID 28 in the region of the digital twin 12.

This data, in other words at least the object variant data 26 with the geometric data 30 and the positional data 32, in particular the geometric data 30, the positional data 32 and the object variant ID 28, now belongs directly or indirectly to the digital twin 23. If the afore-cited data belongs directly to the digital twin 12, this is the result of a copying process, for instance, in which the afore-cited data has been copied from the object variant 22 into the digital twin 12. If the afore-cited data belongs indirectly to the digital twin 12, the digital twin 12 comprises, for instance, a referencing of the data, for instance in the form of what is known as a pointer to the respective object variant 22 or its object variant data 26. Such a referencing is shown in a schematically simplified form in the representation in FIG. 4. The digital twin 12 then comprises, for instance, a data structure in the form of or according to a singly or repeatedly concatenated list, wherein the elements of such a list reference the respective data.

For each object variant 22 determined in this way as belonging to the digital twin 12, the or each geometric object described by means of the geometric data 30 of the respective object variant 22 is positioned according to the positional data 32 of the respective object variant 22.

The digital twin 12 is thus produced. The data included in this way can be indicated, for instance, in particular in the form of a graphical representation of the totality of the geometric data 30, on a computer monitor. Similarly, a dimension drawing can be generated automatically on the basis of the totality of the geometric data 30 and the correct positioning of the graphical objects, which are encoded thereby in each case, relative to one another, and/or a weight value or the center of gravity can be determined.

The representation in FIG. 4 shows a symbolic representation of a digital twin 12, such as is produced as a result of the method illustrated in FIG. 3 for generating a digital twin 12. In the situation shown the digital twin 12 comprises references to the object variants 22 which have been determined as belonging to the digital twin 12 (or references to the object data 26 of that object variant 22 which has been determined as belonging to the digital twin 12).

The digital twin 12 optionally comprises an identifier 42 for its description. The description can be geared to the technical product 10 represented in each case, so that a description such as “electric motor 7.5 kW, terminal box to the side” comes into consideration, for instance.

In the selected, extremely simplified example, the situation implies that the digital twin 12 directly or indirectly comprises all relevant data of the referenced object variants 22, that the referencing defines that the digital twin 12 comprises three objects, namely a first cube (“A”), a second cube (“B”) and a third cube (“C”). By way of the data included in the object variants 22, their object variant data 26 is also immediately available for the digital twin 12. The geometric data 30 included in the object variant data 26 describes the dimension and orientation of the individual cubes. In the real technical product 10 shown in FIG. 1, the situation is however that these cubes are connected to one another and the technical product 10 only results in the connected situation and that there is no arbitrary connection between the individual cubes, but instead a specific connection, namely a connection such that the second cube (“B”) adjoins the first cube (“A”) on the side and that the third cube (“C”) is located on the first cube (“A”).

To this end, beyond the object variant data 26 included in the object variants 22, the positions of the individual cubes are also available immediately in the form of the positional data 32 for each object variant 22. In the representations in FIG. 3 and FIG. 4, the positional data 32 is shown symbolically in the form of a coordinate system. By means of the positional data 32, each object variant 22 determined as belonging to the digital twin 12 is positioned in a coordinate system which applies to the digital twin 12. The positional data 32 describes, essentially in a manner known per se, an offset between a source (x=0, y+0, z=−0) of a global coordinate system of the digital twin 12 and a source of a local coordinate system of each object variant 22, to which its geometric data 30 relates.

The or each object of an object variant 22 described by the geometric data 30 can be positioned correctly, by means of such positional data 32, relative to all objects of any other object variant 22 which belongs to the digital twin 12. With respect to the simple example selected here, the possibility is given of positioning the second cube (“B”) adjacent to the first cube (“A”) and adjoining the first cube in a planar manner and of positioning the third cube (“C”) on the first cube (“A”). For more complex digital twins 12 (and in each case underlying technical products 10), this applies accordingly.

For instance, an object variant 22, which, in the example selected, represents the first cube (“A”), represents the stator housing of an electric motor instead of a cube, an object variant 22, which, in the selected example, represents the second cube (“B”), represents the motor shaft of an electric motor instead of a cube, and an object variant 22, which, in the selected example, represents the third cube (“C”), represents a terminal box of the electric motor instead of a cube. The object variants 22 of the individual components of the electric motor identified as belonging to the digital twin 12 are then also positioned correctly relative to one another by means of the positional data 32.

With the data of the object variants 22 identified as belonging to the digital twin 12, especially with material information or direct weight information included therein, for instance as an integral part of the geometric data 30, a weight value can be determined for the digital twin 12, which corresponds to the weight of the represented technical product 10. With the object variant data 26 and the positional data 32, on the one hand the center of gravity and on the other hand the dimension (length, width, height) of the digital twin 12 can be determined. These values also correspond to the corresponding values of the represented technical product 10.

On account of the access to the product knowledge 20, the digital twin 12 can be easily changed and/or a plurality of digital twins 12 can be generated easily. By inputting a corresponding article code 40, a digital twin 12 of an electric motor is generated, for instance, the terminal box of which is located at the top of the stator housing of the electric motor.

A link between the data included in a digital twin 12 and other databases is possible by means of the object variant ID 28. For instance, on the basis of the object variant IDs 28 included in the digital twin 12, a database with cost information can be accessed successively by means of an object variant ID 28 in each case, in order to determine an item of overall cost information relating to the technical product 10 represented by the digital twin 12.

Although the invention has been illustrated and described in more detail by the exemplary embodiment, the invention is not restricted by the example or examples disclosed and other variations can be derived herefrom by the person skilled in the art without departing from the scope of protection of the invention.

In summary, the innovation proposed here can be described in brief below: a method for classifying product knowledge 20 and for creating a software object which functions as a digital twin 12 of a technical product 10 is specified on the basis of given product knowledge 20, wherein the product knowledge 20 is available in an automatically processible form and comprises, as object variants 22, data records with data for variants of at least one component of the technical product 10, wherein an object variant classification 24 which functions as a unique identifier and geometric data 30 and positional data 32 are assigned to the object variants 22 in each case, wherein each object variant 22, the object variant classification 24 of which matches a predetermined or predeterminable article code 40, is processed as belonging to the digital twin 12, and wherein a positioning of the or each geometric object described by means of the geometric data 30 of the respective object variant 22 is carried out for each object variant 22 belonging to the digital twin 12 according to the positional data 32 of the respective object variant 22.

1.-6. (canceled)

7. A method for automatically creating a software object which functions as a digital twin of a technical product, said method comprising:
providing product knowledge, comprising as object variants, data records having data for different variants of at least one component of the technical product, in an automatically processable form;
assigning each of the object variants an object variant classification which functions as a unique identifier;
assigning geometric data and positional data to each of the object variants;
processing each said object variant, said object variant classification of which matches a predetermined or predeterminable article code, as belonging to the digital twin;
positioning each geometric object described by the geometric data of each of the object variants according to the positional data of each of the object variants for each of the object variants belonging to the digital twin; and
automatically determining a weight value and/or a center of gravity by taking into account all of the object variants belonging to the digital twin.

8. The method of claim 7, further comprising evaluating the object variant classification and the predetermined or predeterminable article code as matching one another when the predetermined or predeterminable article code is an element of a quantity defined by the object variant classification, wherein the object variant classification is present in a form of an expression in a formal language which defines the quantity.

9. The method of claim 7, further comprising automatically generating a dimension drawing by taking into account all the object variants which belong to the digital twin.

10. The method of claim 7, further comprising storing relevant object variant data of all the object variants determined as belonging to the digital twin in order to obtain a description of the digital twin of the technical product.

11. A computer program product for automatically creating a software object which functions as a digital twin of a technical product comprising a computer program embodied in a non-transitory computer readable storage medium, wherein the computer program, when executed on a computer, causes the computer to perform the steps of:
providing product knowledge, comprising as object variants, data records having data for different variants of at least one component of the technical product, in an automatically processable form;
assigning each of the object variants an object variant classification which functions as a unique identifier;
assigning geometric data and positional data to each of the object variants;
processing each said object variant, said object variant classification of which matches a predetermined or predeterminable article code, as belonging to the digital twin;
positioning each geometric object described by the geometric data of each of the object variants according to the positional data of each of the object variants for each of the object variants belonging to the digital twin; and
automatically determining a weight value and/or a center of gravity by taking into account all of the object variants belonging to the digital twin.

12. A digital storage medium with electronically readable control signals, which can interact with a computer for automatically creating a software object which functions as a digital twin of a technical product, wherein the digital storage medium, when interacting with the computer, causes the computer to perform the steps of:
providing product knowledge, comprising as object variants, data records having data for different variants of at least one component of the technical product, in an automatically processable form;
assigning each of the object variants an object variant classification which functions as a unique identifier;
assigning geometric data and positional data to each of the object variants;
processing each said object variant, said object variant classification of which matches a predetermined or predeterminable article code, as belonging to the digital twin;
positioning each geometric object described by the geometric data of each of the object variants according to the positional data of each of the object variants for each of the object variants belonging to the digital twin; and
automatically determining a weight value and/or a center of gravity by taking into account all of the object variants belonging to the digital twin.
